(19) United States
(12) Patent Application Publication
(10) Pub. No.: US 2013/0327634 A1
(43) Pub. Date: Dec. 12, 2013

(54) MISALIGNED SPUTTERING SYSTEMS FOR THE DEPOSITION OF COMPLEX OXIDE THIN FILMS

(71) Applicant: Chang-Beom Eom, Madison, WI (US)

(72) Inventor: Chang-Beom Eom, Madison, WI (US)

(21) Appl. No.: 13/491,715

(22) Filed: Jun. 8, 2012

(51) Int. Cl. C23C 14/35

(52) U.S. Cl. 204/192.1; 204/298.12

(57) ABSTRACT

Thin film sputtering apparatus and methods for depositing thin films using the apparatus are provided. The sputtering apparatus comprise a sputtering chamber that houses a deposition substrate and a sputtering source configured to deposit a thin film of material onto the deposition substrate. The deposition substrate has a deposition surface with a central axis running parallel with the deposition surface normal. The magnetron sputtering source comprises two or more sputtering targets, each sputtering target having a sputtering surface with a central axis running parallel with the sputtering surface normal. The sputtering surfaces are disposed opposite the deposition surface, such that the sputtering surfaces face the deposition surface in a parallel or substantially parallel arrangement, and the central axes of the sputtering surfaces run parallel with, but are transversely offset with respect to, the central axis of the deposition surface.

### REFERENCE TO GOVERNMENT RIGHTS

This invention was made with government support under 0708759 awarded by the National Science Foundation. The government has certain rights in the invention.

### BACKGROUND

Epitaxial complex oxide thin film heterostructures have great potential for numerous device applications due to their enormous range of electrical, magnetic, optical and multiferroic properties. For instance, insulators, high quality metals, dielectrics, ferroelectrics, piezoelectrics, semiconductors, ferromagnetics, transparent conductors, colossal magnetoresistance materials, superconductors and nonlinear optic materials have all been produced using oxide materials. A critical issue in the fabrication of such devices, particularly in industrial scale manufacturing, is the growth of high quality thin films over a large area with uniform thicknesses, properties and stoichiometric compositions.

A variety of thin film growth techniques have been developed to realize high-performance oxide electronic devices. Among them, sputter deposition is a very versatile technique to fabricate high quality thin films of a broad range of materials.

In particular, composite target sputtering can be a very reproducible and easily controllable technique. However, under standard conditions, severe backsputtering of the substrate by a high energy particle (O−, high energy O) causes compositional changes and damages the deposited thin films. Negative oxygen ions generated in the plasma during deposition are accelerated by the cathode's electric field and bombard the film and the underlying substrate. This results in severe degradation of the physical properties of the films and creates defects. Such damage is most severe when the substrate is collinear with the surface normal of the sputtering target (on-axis geometry) and the background pressure is low. Li et al. have sputtered at very high pressure (600 mTorr) in order to reduce the kinetic energy of the particles and, consequently, reduce backscattering. (See, Linker et al., “In situ preparation of Y—Ba—Cu—O superconducting thin films by magnetron sputtering” Appl. Phys. Lett. 52, 1098 (1988).) The uniformity of the resulting film is usually poor since the substrate has to be placed at the center of the sputtering target and away from the erosion area. Better uniformity has been obtained by Xi et al. by using inverted cylindrical magnetron sputtering. (See, Linker et al., Physik-Condensed Matter, 74, 13 (1989).) However, the fabrication of complex oxide cylindrical target and the process can be expensive.

To avoid the backsputtering problem, a 90° off-axis magnetron sputtering technique has been developed. (See, Eom et al., Appl. Phys. Lett. 55, 595 (1989).) With this geometry, the bombarding of the to the substrate by energetic negative ions is reduced. However, one of the drawbacks to 90° off-axis sputtering is a low deposition rate, which is undesirable for the commercialization of oxide-based electronic devices.

### SUMMARY

Magnetron sputtering apparatus and methods for the deposition of thin films and the growth of thin film heterostructures are provided.

The sputtering apparatus comprise: (a) a sputtering chamber; (b) a deposition substrate housed within the sputtering chamber and comprising a deposition surface having a central axis running parallel with the deposition surface normal; and (c) a magnetron sputtering source comprising two or more sputtering targets housed within the sputtering chamber, each sputtering target comprising a sputtering surface having a central axis running parallel with the sputtering surface normal. The sputtering surfaces disposed opposite the deposition surface and their central axes run parallel with, but are transversely offset with respect to, the central axis of the deposition surface.

Methods of using the magnetron sputtering apparatus to deposit a film on a the surface of a deposition substrate comprise: (a) applying a magnetic field around the sputtering targets in the presence of a sputtering gas, whereby the sputtering gas is induced to strike the sputtering surface, thereby depositing a film of sputtering target material onto the deposition surface; and (b) rotating the deposition surface about its central axis during the deposition of the film.

Other principal features and advantages of the invention will become apparent to those skilled in the art upon review of the following drawings, the detailed description, and the appended claims.

### BRIEF DESCRIPTION OF THE DRAWINGS

Illustrative embodiments of the invention will hereafter be described with reference to the accompanying drawings, wherein like numerals denote like elements.

FIG. 1 is a schematic illustration of a sputtering apparatus.

FIG. 2 shows (A) a schematic illustration of the misaligned dual gun sputtering apparatus used in the example; and (B) an enlarged top view of the deposition substrates and heater.

FIG. 3 shows the compositional variation across a 2″ diameter surface obtained using the apparatus of FIG. 2. For comparison the target composition is also shown (in broken lines).

FIG. 4 shows the variation of remnant polarization (Pᵣ) of PMN-PT films across a 2″ diameter surface obtained using the apparatus of FIG. 2. The inset shows the P-E loop of samples located at different distances from the center of the 2″ diameter substrate heater.

FIG. 5 shows the thickness profiles across a 2″ diameter surface obtained using the apparatus of FIG. 2 with a 2″ Si wafer deposition substrate.

FIG. 6 shows the (A) vertical and (B) lateral film thickness profiles for a thin film deposited without substrate rotation.

FIG. 7 is a schematic illustration of a rotatable deposition substrate in a sputtering apparatus having two sets of sputtering targets.

### DETAILED DESCRIPTION

Thin film sputter deposition apparatus and methods for depositing thin films using the apparatus are provided.

The apparatus are capable of depositing high-quality, epitaxial thin films of complex oxides with highly uniform thicknesses at high deposition rates over large areas. The films are formed from sputtering targets, whereby the compositions of the thin films and the sputtering targets having a highly stoichiometric relationship.

The sputtering apparatus comprise a sputtering chamber that houses a deposition substrate and a sputtering source that is configured to deposit a thin film of material onto the deposition substrate. The deposition substrate has a deposition surface with a central axis running parallel with the deposition surface normal. The magnetron sputtering source comprises two or more sputtering targets, each sputtering target having a sputtering surface with a central axis running parallel with the sputtering surface normal. The sputtering surfaces are disposed opposite the deposition surface, such that the sputtering surfaces face the deposition surface in a parallel or substantially parallel arrangement, and the central axes of the sputtering surfaces run parallel with, but are transversely offset with respect to, the central axis of the deposition surface.

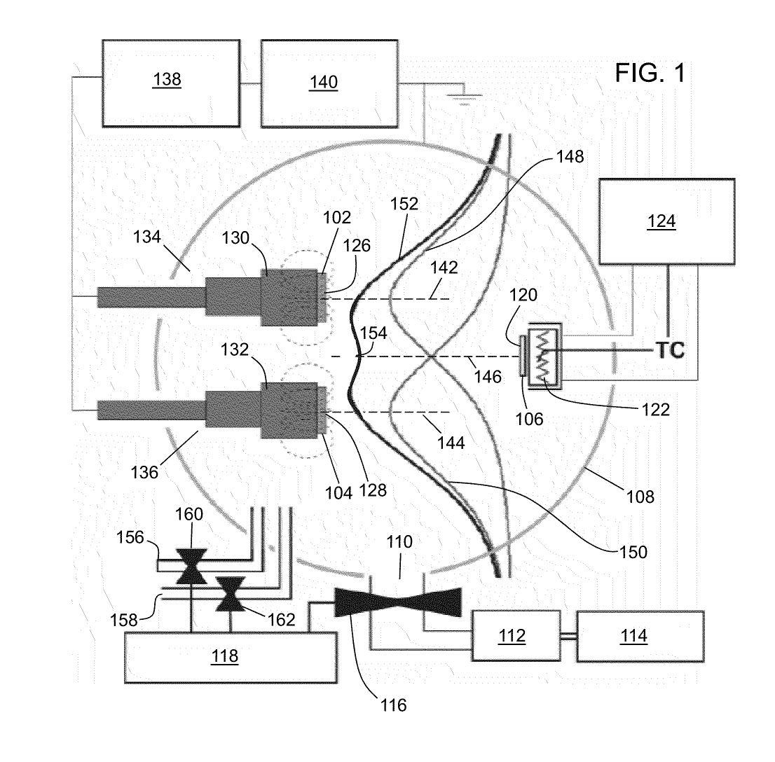

A schematic illustration of an embodiment of a sputtering apparatus is provided in FIG. 1. This apparatus includes two sputtering targets 102, 104 disposed opposite a deposition substrate 106. Sputtering targets 102 and 104 and deposition substrate 106 are housed within a sputtering chamber 108 that can be evacuated through a vacuum port 110 using a high vacuum pump 112 backed by a roughing pump 114. The pressure in chamber 108 can be controlled by pumps 112 and 114 through valve 116 which, in turn, can be controlled with a pressure controller 118.

As shown in FIG. 1, deposition substrate 106 has a planar, or substantially planer, deposition surface 120. (The term ‘substantially’ is used here in recognition of the fact that a surface may not be perfectly planar due to limitations in the fabrication processes used to make the substrate.) Deposition substrate 106 can be mounted to a heater 122 that is configured to heat the deposition substrate during thin film deposition. The temperature of deposition substrate 106 can be monitored using a thermocouple (denoted ‘TC’), which can be controlled using a power source and heater controller 124. In order to provide for a more uniform thickness of the deposited film, deposition substrate 106 is rotatably mounted within the sputtering chamber, such that the substrate is configured to rotate about its central axis during thin film deposition. The diameter of deposition surface 120 will depend on a variety of factors, including the intended use of the heterostructure that results from the thin film deposition. However, the sputtering apparatus can be designed to deposit thin films over a large surface area. Thus, by way of illustration only, the diameter of the deposition surface can be at least 1 inch, at least 2 inches, at least 4 inches, at least 8 inches and at least 10 inches. The material from which the deposition substrate is made will depend on the thin film to be deposited. A wide variety of substrate materials may be employed provided the thin film to be deposited on the substrate is able to grow (e.g., via epitaxial growth) on that material. Examples of suitable deposition substrates for the growth of thin film oxides include glass, silicon, silicon with epitaxial template layers, aluminum oxide, yttrium-stabilized zirconia and perovskite substrates.

The magnetron sputtering source of FIG. 1 includes sputtering targets 102 and 104 which have planar, or substantially planar, sputtering surfaces 126 and 128, and further includes magnets 130 and 132 mounted to the sputtering targets, opposite the sputtering surfaces. Magnets 130 and 132 may themselves be mounted to insulating/shield arms 134 and 136. An RF or DC power supply 138 controlled by a matching network 140 is connected to the magnets and configured to apply a negative voltage to the sputtering targets.

Sputtering surfaces 126 and 128 are disposed opposite (facing) deposition surface 120 with their central axes 142 and 144 running parallel with, but transversely offset from, the central axis 146 of deposition surface 120. In this sense, the sputtering surfaces and deposition surface are parallel (or substantially parallel), but misaligned with respect to one another. As a result, the individual material sputtering distributions 148 and 150 for the two sputtering targets have peaks that are offset with respect to central axis 146 (i.e., they do not have a common sputtering focal point). The combined material sputtering distribution 152 for the sputtering targets is symmetric around central axis 146. In the embodiment shown here, the cross-section of the combined material sputtering distribution 152, which is taken along an axis running a line that bisects the sputtering surface of both sputtering targets, is concave at its midpoint 154. The exact cross-sectional profile of the combined material sputtering distribution will depend on the dimensions of the sputtering targets and the separation between the targets. This geometry, in combination with a rotating substrate, facilitates the deposition of a thin film having a highly uniform thickness over the entire deposition surface, and can be achieved by, for example, spacing the sputtering surfaces such that their center-to-center distance is substantially equal to, or greater than, the diameter of the deposition surface.

Although the embodiment of the apparatus shown in FIG. 1 has only two sputtering targets, the apparatus may include a greater number. Thus, in some embodiments, the apparatus has 4, 6, 8, 10 or even more targets. In a typical design, the sputtering targets are arranged symmetrically about the central axis of the deposition surface. That is, they are arranged such that they are equi-spaced from one another and from the central axis of the deposition surface.

Due to space constrains, it may be impractical to have more than four sputtering targets arranged around the central axis of a deposition substrate. Therefore, if more than two different materials are to be deposited, the deposition substrate can moved within the sputtering chamber from a first position for the deposition of a layer or layers of a thin film by a first set of sputtering targets to a second position for the deposition of a layer or layers of the thin film by a second set of sputtering targets. For example, the deposition substrate may be mounted to a translational stage configured to translate the substrate from a first position in the xy-plane (i.e., the plane perpendicular to the central axes of the sputtering surfaces and the deposition surface) to a second position in the xy-plane. In the design, a first set of sputtering targets (e.g., four sputtering targets) can be arranged such that their sputtering surfaces run parallel to (or substantially parallel to) the deposition surface, with their central axes being misaligned with respect to, and distributed symmetrically about, the central axis of the deposition surface when the deposition surface is in the first position. A second set of sputtering targets (e.g., four sputtering targets) can be arranged such that their sputtering surfaces run parallel to (or substantially parallel to) the deposition surface, with their central axes being misaligned with respect to, and distributed symmetrically about, the central axis of the deposition surface when the deposition surface is in the second position. This design can be expanded to deposit greater number of materials by using a greater number of sputtering target sets and greater number of substrate positions in the xy-plane.

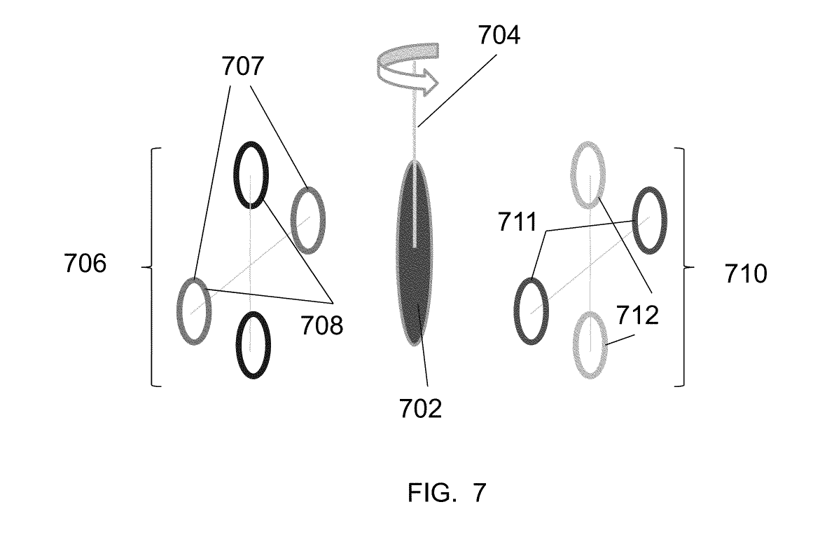

Alternatively, the deposition substrate may be mounted to a rotational stage configured to rotate the substrate about an axis running parallel to the deposition substrate from a first position to a second position. Such a configuration is shown in FIG. 7, which provides a schematic illustration of a deposition substrate 702 that can rotate 180° about axis 704 from a first position in which the deposition surface is facing a first set of sputtering targets 706 to a second position in which the deposition surface is facing a second set of sputtering targets 710. Each set of sputtering targets comprises two subset pairs (pairs 707 and 708 for set 706 and pairs 711 and 712 for set 708), wherein the two targets in each pair are disposed opposite one another and comprise the same material.

The sputtering targets may be composed of a wide range of materials and may comprise two or more elements. Examples of materials from which the sputtering targets may be comprised include metals, semiconductors, oxides and combinations thereof. In some embodiments, the sputtering target material is an oxide. The oxide may be, for example, a dielectric oxide, a ferroelectric oxide, a ferromagnetic oxide, a piezoelectric oxide, a semiconducting oxide, a superconducting oxide or a non-linear optical oxide. The apparatus are particularly well-suited for the deposition of thin films of materials for which backsputtering is severe and/or stoichiometric control is difficult using other known sputtering techniques. Such thin films include thin films comprising highly volatile elements, such as lead and bismuth, and thin films comprising complex oxides composed of 3, 4, 5, 6 or more elements. Specific examples of materials from which the sputtering targets and/or deposited thin films can be made include lead zirconate titanate (PZT), lead magnesium niobate-lead titanate (PNM-PT), BiFeO₃ and yttrium barium copper oxide (YBCO).

The sputtering targets can comprise the same material or different materials. For example, if only a single layer of material is to be deposited, the two or more sputtering targets can have the same material composition. However, if a multilayered thin film heterostructure is to be grown, sputtering targets having different material compositions can be used. In this design at least two targets having the same material composition can be used to deposit each material layer in the thin film, wherein the at least two targets are desirably arranged symmetrically about the central axis of the deposition surface. For example, a system designed to deposit alternating layers of material “A” and material “B” to provide a heterostructure having an ABABAB pattern can comprise two targets composed of material A arranged directly across from one another on opposite sides of the central axis of the deposition surface and two targets composed of material B arranged directly across from one another on opposite sides of the central axis of the deposition surface.

Thin films can be deposited on a deposition substrate using the present apparatus by applying a magnetic field around the sputtering targets in the presence of a sputtering gas, whereby the resulting negative voltage induces as atoms and/or molecules of the sputtering gas strike the sputtering surface, thereby ejecting material from the sputtering target which is deposited as a sputtered film of sputtering target material onto the deposition surface. The sputtering gas, which may a pure gas, such as an inert gas, or a mixture of gases, such as a mixture of an inert gas and oxygen, can be introduced into sputtering chamber 108 from one or more sputtering gas sources 156, 158 in fluid communication with the sputtering chamber. The flow of sputtering gas in the sputtering chamber can be controlled via valves 160, 162 and pressure controller 118. High deposition rates can be achieved using the present apparatus. For example thin films can be deposited at a rate of 0.3 Å/sec or faster. This includes deposition rates of at least 0.5 Å/sec and deposition rates of at least 0.6 Å/sec.

If layers of different materials are to be deposited, the RF or DC power for each set of sputtering targets corresponding to a given material can be turned on and off sequentially. Alternatively, shutters can be used to selectively and sequentially block the sputtering flux for a given set of sputtering targets. In this manner, heterostructures having many different material layers (e.g., ≧2, ≧3, ≧5, and ≧10) can be grown. Artificial layered superlattices are an example of a type of multilayered heterostructure that can be grown in this way.

The deposited films are characterized by highly uniform thicknesses. For example, some embodiments of the apparatus and methods deposit thin films having a thickness variation of no greater than ±10%. This includes thin films having a thickness variation of no greater than ±8%, no greater than ±6% and no greater than ±4%. The thickness of the deposited films will depend, in part, of the intended use of the films. However, the films can be very thin. For example, some embodiments of the deposited films have a thickness of no greater than about 10 nm.

The deposited films can also be characterized by a highly stoichiometric relationship between the material composition of the thin film and the material composition of the targets from which it is deposited. The stoichiometric relationship for a given element in the deposited film and the sputtering target can be measured as the cation ratio for that element to the total cation content for all elements in the film or target (in atomic percent). Thus, some embodiments of the present apparatus and methods deposit a thin film in which the cation ratio for a given element differs from that in the sputtering target by no greater than about 5%. This includes embodiments in which the cation ratio for an element in the deposited film differs from the cation ratio for the element in the sputtering target by no greater than about 3% and further includes embodiments in which the cation ratio for an element in the deposited film differs from the cation ratio for the element in the sputtering target by no greater than about 1%. These highly uniform, highly stoichiometric films can be deposited over large deposition surface areas, including areas of at least 2 inches, at least 4 inches, at least 8 inches and at least 12 inches.

### Example

This example illustrates a sputtering method that employs a misaligned sputtering geometry with two parallel magnetron sputtering guns and a substrate offset exactly in between. The results show the integration of a higher level of deposition flux into the films relative to a sputtering method that employs a 90° off-axis sputtering geometry. Using this misaligned geometry with substrate rotation, very uniform and high quality epitaxial 0.67Pb(Mg_{1/3}Nb_{2/3})O₃-0.33PbTiO₃ (PMN-PT) piezoelectric thin films were grown on (001) SrTiO₃ deposition substrates over a 2″ diameter area.

PMN-PT was chosen for this study as a model system to investigate the sputtering technique since it is significantly more sensitive to growth conditions than other simple oxides. PMN-PT is difficult to grow as a high quality film with a stoichiometric composition. Furthermore, as a giant piezoelectric relaxor ferroelectric, single crystal PMN-PT shows strain levels ten times those of PZT ceramics. (See, Park et al., IEEE Trans. Ultrason Ferroelectr. Freq. Control. 44, 1140 (1997).) It also has a large electromechanical coupling coefficient of k₃₃ ˜0.9. (See, Park et al., J. Appl. Phys. 82, 1804 (1997).) The piezoelectric properties of PMN-PT are strongly dependent on the composition ratio between PMN and PT; they are maximized near the morphotrophic phase boundary composition where the tetragonal and rhombohedral phases meet each other. (See, Park et al., IEEE Trans. Ultrason Ferroelectr. Freq. Control. 44, 1140 (1997).) Furthermore, the volatile PbO constituent makes it difficult to grow stoichiometric PMN-PT films with prevalent formation of the pyrochlore phase, resulting in the degradation of piezoelectric properties. (See, Bu et al., Appl. Phys. Lett. 79, 3482 (2001).) Uniform deposition of PMN-PT films over large areas is crucial in order to achieve a high yield of piezoelectric devices with consistent performance. Thus, precise and reproducible control over composition, stoichiometry, and thickness is highly desirable during the deposition process.

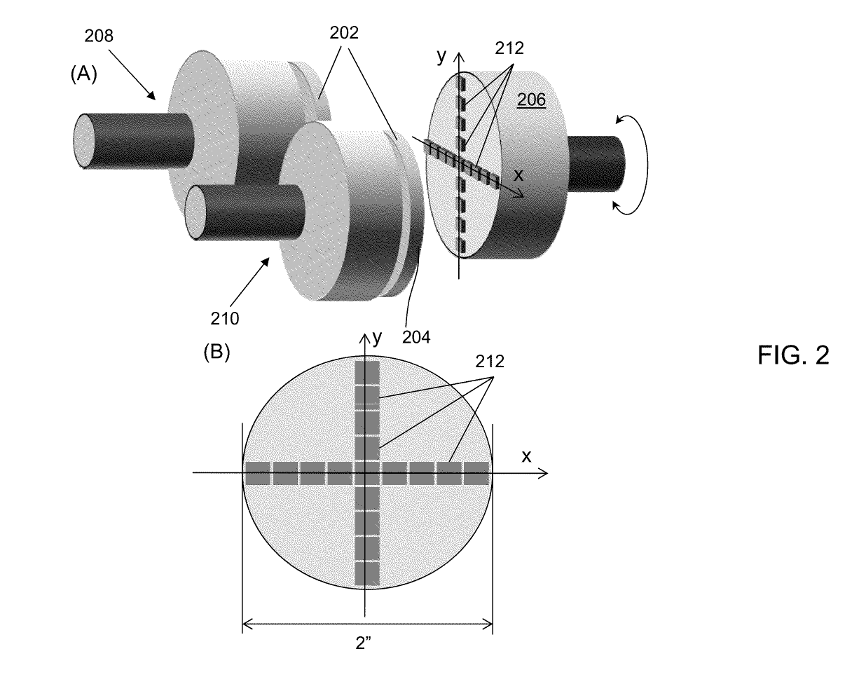

FIG. 2(A) is a schematic diagram of the sputtering apparatus using a misaligned dual gun sputtering geometry that was employed in this example. The reference axes along which the variation in deposited film quality was measured are shown. Two 2″ diameter planar magnetron sputtering targets 202, 204 were positioned with a lateral (center-to-center) separation of 3″. A 2″ diameter deposition substrate heater 206 was offset perpendicularly from the sputtering surfaces of sputtering targets 202 and 204 by 1.5″. The sputtering targets were PMN-PT ceramic targets sintered with 5% excess PbO mounted in the sputtering guns 208, 210. To improve the uniformity of the thin films, deposition substrate heater 206 was rotated by oscillatory motion during the deposition at a speed of 10 rpm (revolution per minute). Each oscillation consisted of a 180 degree clockwise motion followed by another 180 degree counterclockwise motion. A plurality of deposition substrates 212 of (001) SrTiO₃ with a 4° miscut along [100] were used in order to investigate the properties of the deposited films as a function of their transverse offset. FIG. 2(B) shows a top view of the arrangement of the deposition substrates on the substrate heater. The 4° miscut is favorable for growing high quality thin films with volatile species. (See, Bu et al., Appl. Phys. Lett. 79, 3482 (2001) and Baek et al., Science 334, 958 (2011).) 50 nm-thick SrRuO₃ layers were deposited on top of the SrTiO₃ substrates as a bottom electrode by 90° off-axis sputtering as described in Eom et al., Appl. Phys. Lett. 63, 2570 (1993) and Eom et al., Science 258, 1799 (1992).

To investigate the effects of spatial distribution on the chemical composition and electrical properties of the PMN-PT thin films, the 5 mm×5 mm SrRuO₃/SrTiO₃ deposition substrates were mounted on the substrate heater along two principal directions: vertical (perpendicular to a line connecting the sputtering target centers; denoted by the y-axis in the figure) and lateral (parallel to a line connecting the sputtering target centers; denoted by the x-axis in the figure), as shown in FIG. 2. The PMN-PT thin films were grown at 630° C. A mixture of Ar and O₂ gas with a 17:3 flow ratio was used as the sputtering gas at a total background pressure of 500 mTorr. 100 watts of radio frequency (RF) power was applied for 4 hours. After deposition of the PMN-PT film, an oxygen gas pressure of 300 Torr was maintained in the sputtering chamber while the samples were allowed to cool to room temperature in order to reduce oxygen vacancies in the films. A Pt film was then deposited at room temperature by on-axis sputtering and patterned by a lift-off process to form top electrodes for electrical measurements.

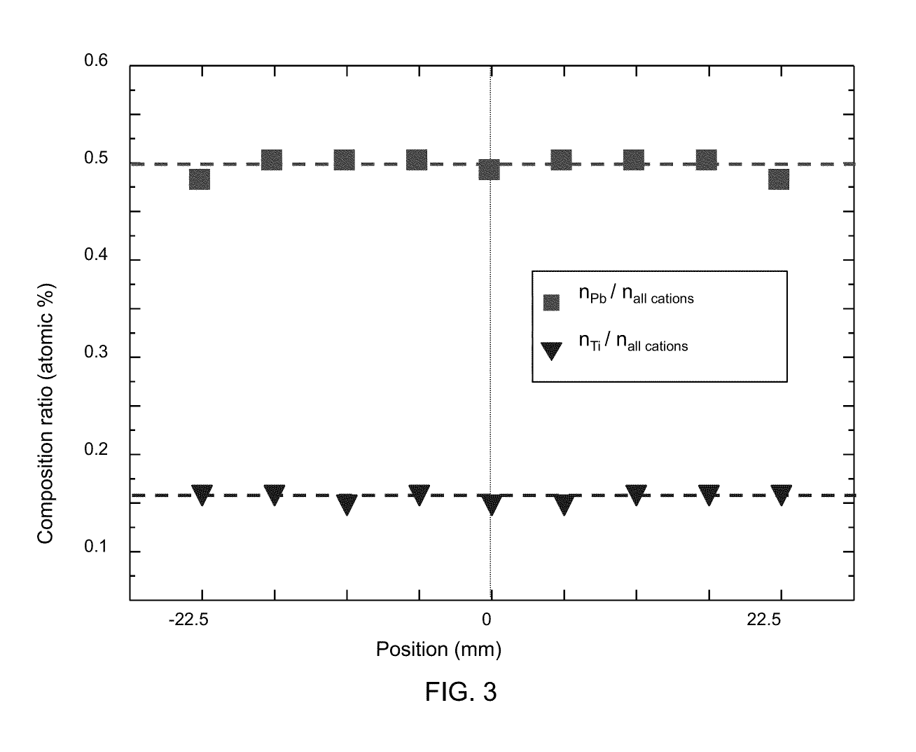

Chemical compositions of the films were determined by wavelength dispersive spectroscopy (WDS). FIG. 3 shows the Pb/(Pb+Mg+Nb+Ti) and Ti/(Pb+Mg+Nb+Ti) cation ratio distributions over a 2″ radial distance. The target composition is shown in dotted lines. The nominal Pb/(Pb+Mg+Nb+Ti) and Ti/(Pb+Mg+Nb+Ti) cation ratios of the ceramic sputtering targets should be 0.5 and 0.165, respectively. The Ti/(Pb+Mg+Nb+Ti) cation ratio is important in determining the intrinsic piezoelectric properties of PMN-PT films because it affects the crystal symmetry of PMN-PT. (See, Park et al. J. Appl. Phys., 82, 1804 (1997).) The results show that the Ti/(Pb+Mg+Nb+Ti) cation ratio in the films was the same as the nominal composition of the sputtering target and very uniform across the 2″ diameter area. This indicates that the intrinsic piezoelectric properties of PMN-PT films would also be uniform through the 2″ diameter area. Lead stoichiometry is important since it dominantly affects film stoichiometry due to the volatility of PbO. Lead-deficient PMN-PT samples tend to form lead-deficient pyrochlore phases with higher electrical leakage. The Pb/(Pb+Mg+Nb+Ti) cation ratio of the PMN-PT films was 0.5, which is also the same as the nominal composition of the sputtering target and very uniform across the 2″ diameter area.

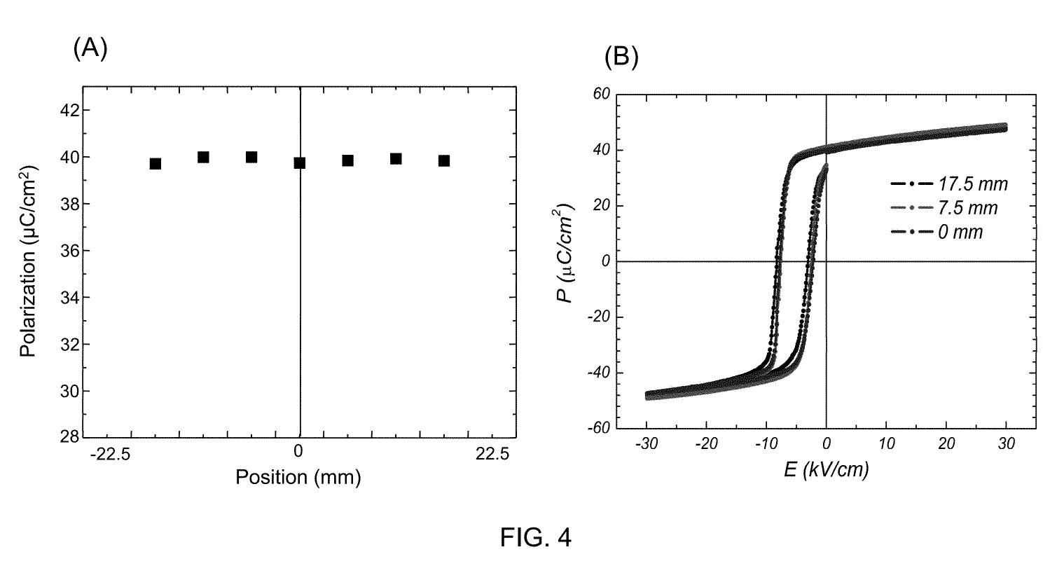

The electrical properties of the PMN-PT films across a 2″ diameter were characterized by measuring the polarization vs. electric field (P-E) loop by contacting the patterned Pt top electrodes. A switching frequency of 1 kHz was used, which is sufficiently high to rule out the possible contribution of leakage current to remnant polarization (Pᵣ). The P-E measurements showed all the PMN-PT films had a square-like hysteresis loop. The films deposited over a 2″ diameter area consistently displayed identical P-E loops, as shown in the inset of FIG. 4. FIG. 4 shows the value of the remnant polarization, Pᵣ of the PMN-PT films along the 2″ diameter. Within ±1 μC/cm² of the measurement error, all the PMN-PT films showed a uniform Pᵣ of ˜40 μC/cm².

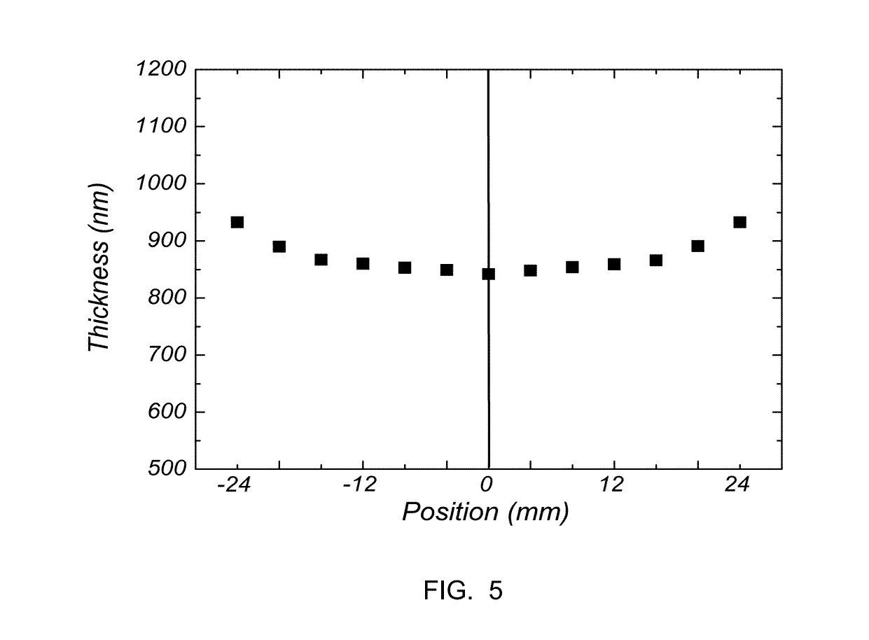

The thicknesses of the PMN-PT films were measured by a surface profilometer. PMN-PT thin films were deposited at room temperature using 2″ diameter Si wafers as deposition substrates. A grid consisting of 200 μm wide lines spaced every 0.25″ was prepared on these films by photolithography and chemical etching. The thickness was measured every 0.25″ on the film as the depth of the trench at that point, using an Alpha Step 500 Surface Profiler. The thickness of the films ranged from 850 nm to 930 nm. The error in the measured thickness values was less than ±10 nm. FIG. 5 shows the thickness profile obtained along the vertical axis on a rotating 2″ Si wafer. The thickness uniformity was ±6% over the 2″ diameter area. The average deposition rate was 0.6 Å/sec which is roughly 5 times faster than 90 degree off-axis sputtering.

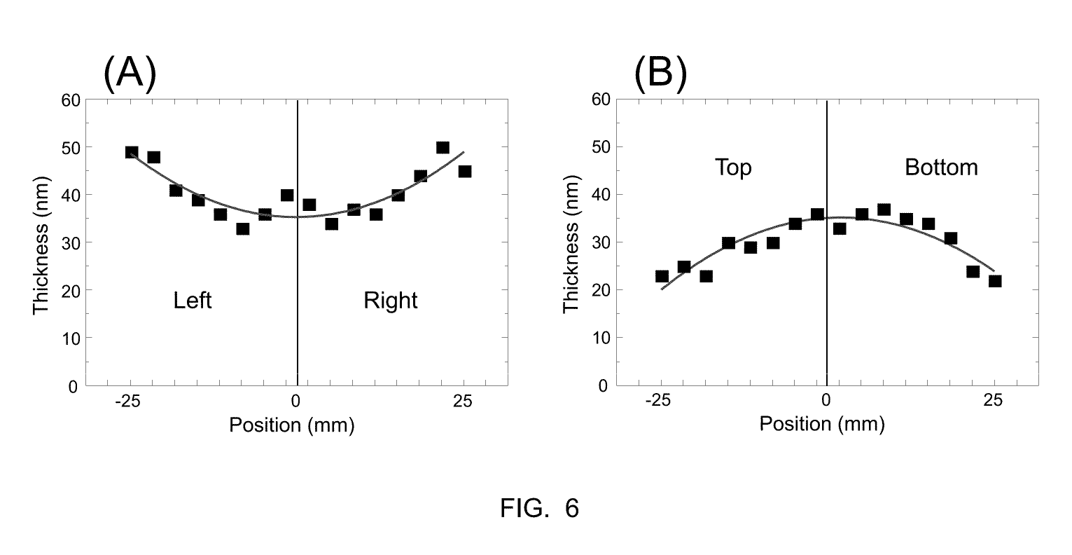

In order to illustrate the improvement in film thickness uniformity resulting from the rotation of the deposition substrate, the film thickness profile was also measured for a thin film deposited on a stationary (non-rotating) deposition substrate. FIG. 6 shows the results of the thickness measurements taken along lateral (A) and vertical (B) directions, respectively. As shown is these figures, deposition on the stationary substrate results in a substantially less uniform thickness distribution having a concave profile along the lateral direction and a convex profile along the vertical direction. However, upon rotation of the substrate the flux is averaged, resulting in a more uniform thickness profile across the deposited film.

Excellent uniformity of thickness, composition and properties was obtained over a 2″ diameter area with no noticeable variation of composition and electrical properties by employing 2″ diameter sputtering targets. By increasing the size of the target and the spacing between the dual sputtering surfaces a better uniformity over a larger area can be achieved. In addition, by using larger diameter targets, the deposition rate can be further increased.

The word “illustrative” is used herein to mean serving as an example, instance, or illustration. Any aspect or design described herein as “illustrative” is not necessarily to be construed as preferred or advantageous over other aspects or designs. Further, for the purposes of this disclosure and unless otherwise specified, “a” or “an” means “one or more”. Still further, the use of “and” or “or” is intended to include “and/or” unless specifically indicated otherwise.

The foregoing description of illustrative embodiments of the invention has been presented for purposes of illustration and of description. It is not intended to be exhaustive or to limit the invention to the precise form disclosed, and modifications and variations are possible in light of the above teachings or may be acquired from practice of the invention. The embodiments were chosen and described in order to explain the principles of the invention and as practical applications of the invention to enable one skilled in the art to utilize the invention in various embodiments and with various modifications as suited to the particular use contemplated. It is intended that the scope of the invention be defined by the claims appended hereto and their equivalents.

What is claimed is:

1. A sputtering apparatus comprising:
(a) a sputtering chamber;
(b) a deposition substrate housed within the sputtering chamber and comprising a deposition surface having a central axis running parallel with the deposition surface normal, wherein the deposition substrate is mounted to a rotation mechanism configured to allow the deposition surface to rotate about its central axis; and
(c) a magnetron sputtering source comprising two or more sputtering targets housed within the sputtering chamber, each sputtering target comprising a sputtering surface having a central axis running parallel with the sputtering surface normal, the sputtering surfaces disposed opposite the deposition surface;
wherein the central axes of the sputtering surfaces run parallel with, but are transversely offset with respect to, the central axis of the deposition surface and further wherein the sputtering surfaces are disposed symmetrically around the central axis of the deposition surface.

2. The apparatus of claim 1, wherein the deposition surface and the sputtering surfaces are positioned with respect to each other such that sputtering from the sputtering surfaces will deposit a film on the deposition surface, the film having a thickness variation of no greater than ±6%.

3. The apparatus of claim 1, wherein the two or more sputtering targets each have the same chemical composition.

4. The apparatus of claim 1, comprising four of the sputtering targets, wherein two of the four sputtering targets have a first chemical composition and the other two of the four sputtering targets have a second chemical composition that differs from the first chemical composition.

5. The apparatus of claim 1, wherein the sputtering targets comprise a piezoelectric oxide.

6. The apparatus of claim 1, wherein the sputtering targets comprise a superconducting oxide.

7. The apparatus of claim 1, wherein the sputtering targets comprise a multiferroic oxide.

8. The apparatus of claim 1, wherein the sputtering targets comprise Pb, Bi or a combination thereof.

9. A method for depositing a film on a substrate using the apparatus of claim 1, the method comprising applying a magnetic field around the sputtering targets in the presence of a sputtering gas, whereby the sputtering gas is induced to strike the sputtering surface, thereby depositing a film of sputtering target material onto the deposition surface, and rotating the deposition surface about its central axis during the deposition of the film.

10. The method of claim 9, wherein the deposition surface and the sputtering surfaces are positioned with respect to each other such that the film has a thickness variation of no greater than ±6%.

11. The method of claim 9, wherein the apparatus comprises at least four sputtering targets and the step of applying a magnetic field around the sputtering targets comprises applying a magnetic field around a first set of the sputtering targets, the first set of sputtering targets comprising at least two sputtering targets that have a first material composition, to deposit a layer having the first material composition onto the deposition surface, and subsequently applying a magnetic field around a second set of the sputtering targets, the second set of sputtering targets comprising at least two sputtering targets that have a second material composition that differs from the first material composition, to deposit a layer having the second material composition onto the layer having the first material composition.
